(19) United States
(12) Patent Application Publication
(10) Pub. No.: US 2017/0340995 A1
(43) Pub. Date: Nov. 30, 2017

(54) CHEMICAL LIQUID SUPPLY SYSTEM AND CHEMICAL LIQUID SUPPLY METHOD

(71) Applicant: TOSHIBA MEMORY CORPORATION, Minato-ku (JP)

(72) Inventor: Makoto AIDA, Yatomi (JP)

(73) Assignee: TOSHIBA MEMORY CORPORATION, Minato-ku (JP)

(21) Appl. No.: 15/256,778

(22) Filed: Sep. 6, 2016

(30) Foreign Application Priority Data
May 26, 2016 (JP) 2016-105530

(51) Int. Cl. B01D 35/143; B08B 3/08; B01D 37/04; H01L 21/02; B01D 35/02

(52) U.S. Cl. CPC B01D 35/143; H01L 21/0206; B01D 35/023; B01D 37/046; B08B 3/08

(57) ABSTRACT

According to one embodiment, there is provided a chemical liquid supply system including a chemical liquid supply apparatus and a monitoring apparatus. The chemical liquid supply apparatus includes a nozzle, a filter, a first pressure gauge, and a second pressure gauge. The first and the second pressure gauge are disposed on the pipeline, respectively at a chemical liquid supply-source side and chemical liquid delivery side of the filter. The monitoring apparatus is configured to determine a state of the filter based on first differential pressure time information in which a differential pressure is acquired in a period until a time point of a lapse of a predetermined time since a start of pneumatic feeding of the chemical liquid to the nozzle. The differential pressure is a difference between a first pressure value measured by the first pressure gauge and a second pressure value measured by the second pressure gauge.

### CROSS-REFERENCE TO RELATED APPLICATIONS

This application is based upon and claims the benefit of priority front Japanese Patent Application No. 2016-105530, filed on May 26, 2016; the entire contents of which are incorporated herein by reference.

### FIELD

Embodiments described herein relate generally to a chemical liquid supply system and a chemical liquid supply method.

### BACKGROUND

In general, in a manufacturing process of semiconductor devices, a series of processes are performed such that: a photo-resist is applied onto a semiconductor wafer (which will be referred to as “wafer”, hereinafter) treated as a processing object; then circuit patterns are transferred in a reduced state onto the photo-resist by use of a photolithography technique; and then development is performed to the photo-resist. In a process of this kind, a processing liquid, such as a resist liquid or developing solution, is supplied onto the wafer or the like. Air bubbles and/or particles may be mixed in the processing liquid due to various causes. If the processing liquid in which air bubbles and/or particles are mixed is supplied onto a wafer or the like, the applied coating comes to have an abnormality or defects.

Accordingly, a filter for removing air bubbles and/or particles mixed in a processing liquid is disposed in a piping passage of the processing liquid. When the filter is mounted, a treatment is performed so that the filter will not have air bubbles remaining therein. Further, as regards replacement of the filter, filter replacement is performed before the filter falls into a break-through state. However, conventional techniques are insufficient to detect a state of the filter, such as the break-through of the filter or the presence of air bubbles in the filter.

### BRIEF DESCRIPTION OF THE DRAWINGS

FIG. 1 is a view showing a schematic configuration example of a chemical liquid supply system according to a first embodiment;

FIG. 2 is a view schematically showing the relationship between differential pressure and time, where a secondary side pressure gauge does not have a pressure control function;

FIG. 3 is a view schematically showing the relationship between differential pressure and time, where a secondary side pressure gauge has a pressure control function;

FIG. 4 is a flow chart showing an example of the procedure of a chemical liquid passing treatment performed when a filter is attached;

FIG. 5 is a flow chart showing an example of the process procedure of a filter state determination method according to the first embodiment;

FIG. 6 is a view showing a schematic configuration example of a chemical liquid supply system according to a second embodiment;

FIG. 7 is a flow chart showing an example of the process procedure of a filter state determination method according to the second embodiment; and

FIG. 8 is a view showing the hardware configuration of a monitoring apparatus.

### DETAILED DESCRIPTION

In general, according to one embodiment, there is provided a chemical liquid supply system including: chemical liquid supply apparatus configured to supply a chemical liquid onto a processing object; and a monitoring apparatus. The chemical liquid supply apparatus includes a nozzle, a filter, a first pressure gauge, and a second pressure gauge. The nozzle is configured to supply the chemical liquid, through a pipeline, onto the processing object. The filter is disposed on the pipeline. The first pressure gauge is disposed on the pipeline, at a chemical liquid supply-source side of the filter. The second pressure gauge is disposed on the pipeline, at a chemical liquid delivery side of the filter. The monitoring apparatus is configured to determine a state of the filter based on first differential pressure time information. The first differential pressure time information is information it which a differential pressure is acquired in a period until a time point of a lapse of a predetermined time since a start of pneumatic feeding of the chemical liquid to the nozzle. The differential pressure is a difference between a first pressure value measured by the first pressure gauge and a second pressure value measured by the second pressure gauge.

Exemplary embodiments of a chemical liquid supply system and a chemical liquid supply method will be explained below in detail with reference to the accompanying drawings. The present invention is not limited to the following embodiments.

### First Embodiment

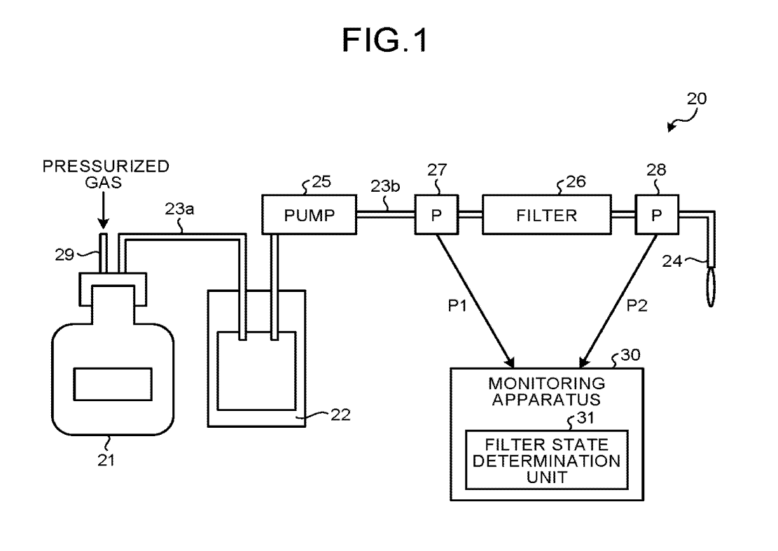

FIG. 1 is a view showing a schematic configuration example of a chemical liquid supply system according to a first embodiment. The chemical liquid supply system includes a chemical liquid supply apparatus 20 and a monitoring apparatus 30. The chemical liquid supply apparatus 20 includes a chemical liquid supply part 21, a chemical liquid buffer 22, a chemical liquid supply pipeline 23, a nozzle 24, a pump 25, a filter 26, a primary side pressure gauge 27, and a secondary side pressure gauge 28.

The chemical liquid supply part 21 is formed of a container that stores a chemical liquid and supplies the chemical liquid. The chemical liquid is a resist liquid, developing solution, or cleaning liquid, for example. The chemical liquid supply part 21 has strength with which it can be hardly deformed by pressure. The chemical liquid supply part 21 is connected to the chemical liquid buffer 22 through a chemical liquid supply pipeline 23a. Further, one end of a pressurized gas supply pipeline 29 is connected to the chemical liquid supply part 21. The other end of the pressurized gas supply pipeline 29 is connected to a pressurized gas supply unit (not shown). As the pressurized gas, nitrogen gas or the like may be used. According to this configuration, when the pressurized gas is supplied through the pressurized gas supply pipeline 29, the chemical liquid is supplied from inside the chemical liquid supply part 21 to the chemical liquid buffer 22 through the chemical liquid supply pipeline 23a.

The chemical liquid buffer 22 is a container for temporarily storing the chemical liquid supplied from the chemical liquid supply part 21. The chemical liquid buffer 22 is disposed so that the chemical liquid stored in the chemical liquid buffer 22 can be supplied to the nozzle 24, even when the chemical liquid inside the chemical liquid supply part 21 runs out. In other words, the chemical liquid buffer 22 serves as a backup container for replacement of the chemical liquid supply part 21.

A chemical liquid supply pipeline 23b is a pipeline for supplying the chemical liquid from the chemical liquid buffer 22 to the nozzle 24. The nozzle 24 is used for delivering the chemical liquid onto a processing object. As the processing object, an example is a semiconductor substrate or glass substrate. The pump 25 supplies the chemical liquid from inside the chemical liquid buffer 22 through the chemical liquid supply pipeline 23b toward the nozzle 24, The filter 26 removes air bubbles and/or particles from the chemical liquid. The filter 26 is disposed on the chemical liquid supply pipeline 23b that connects the chemical liquid buffer 22 to the nozzle 24.

The primary side pressure gauge 27 is disposed at the upstream side of the filter 26, and the secondary side pressure gauge 28 is disposed at the downstream side of the filter 26. The primary side pressure gauge 27 measures a pipeline pressure on the primary side of the filter 26, and the secondary side pressure gauge 28 measures a pipeline pressure on the secondary side of the filter 26. The pressure measurement results obtained by the primary side pressure gauge 27 and the secondary side pressure gauge 28 are output to the monitoring apparatus 30.

The monitoring apparatus 30 includes a filter state determination unit 31 configured to determine a state of the filter 26 based on the pipeline pressure P1 on the primary side of the filter 26 measured by the primary side pressure gauge 27 and the pipeline pressure P2 on the secondary side of the filter 26 measured by the secondary side pressure gauge 28. The filter state determination unit 31 is configured to detect a change in the film resistance of the filter 26 based on the pipeline pressure P1 on the primary side of the filter 26 and the pipeline pressure P2 on the secondary side of the filter 26. A differential pressure ΔP between the primary side pipeline pressure P1 and the secondary side pipeline pressure P2, which are on the fore and back sides of the filter 26, can be expressed by the following formula (1). Here, α is a constant given in consideration of the influence of a difference between days, such as atmospheric pressure variation.

ΔP=(film resistance+pipeline resistance)×chemical liquid viscosity+α (1)

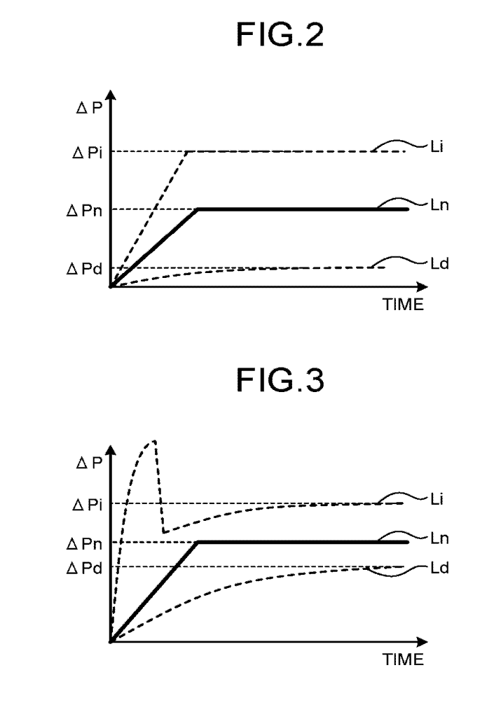

As expressed in the (1), if the pipeline resistance and the chemical liquid viscosity are assumed to be constant, an increase in the film resistance of the filter 26 brings about an increase in the differential pressure ΔP, and a decrease in the film resistance of the filter 26 brings about a decrease in the differential pressure ΔP. FIG. 2 is a view schematically showing the relationship between the differential pressure and time, where the secondary side pressure gauge does not have a pressure control function. In FIG. 2, the horizontal axis indicates a lapse of time since the time point of activation of the pump 25, and the vertical axis indicates the differential pressure ΔP between the primary side pipeline pressure and the secondary side pipeline pressure of the filter 26. When the filter 26 is in the normal state, as shown in a curved line Ln, the differential pressure ΔP increases gradually from the time point of activation of the pump 25, and then the differential pressure PP becomes an almost constant value ΔPn after a certain time point.

On the other hand, when the film resistance of the filter 26 has increased, as shown in a curved line Li, the differential pressure ΔP increases from the time point of activation of the pump 25, and then the differential pressure ΔP becomes an almost constant value ΔPi after a certain time point. The ΔPi is larger than the ΔPn. This means that the chemical liquid cannot flow through the filter 26 without help of a large pressure. As a cause of this state, it is thought that the filter 26 has been clogged.

Further, when the film resistance of the filter 26 has decreased, as shown in a curved line Ld, the differential pressure PP does not increases so much from the time point of activation of the pump 25, and then the differential pressure ΔP becomes an almost constant value ΔPd. The ΔPd is smaller than the ΔPn. This means that the chemical liquid can flow through the filter 26 more easily. As a cause of this state, it is thought that the filter 26 is in a break-through state or that the filter 26 has air bubbles present therein. Here, the “break-through” represents a state providing no absorption ability because the absorbing rate and the desorbing rate are balanced in an equilibrium state.

Although FIG. 2 shows a case where the secondary side pressure gauge 28 does not have a pressure control function, but there is a case where the secondary side pressure gauge 28 has a pressure control function. FIG. 3 is a view schematically showing the relationship between the differential pressure and time, where the secondary side pressure gauge has a pressure control function. When the film resistance of the filter 26 has increased, as shown in a curved line Li, the differential pressure ΔP increases rapidly from the time point of activation of the pump 25. This is because the secondary side pressure gauge 28 exerts a pressure adjusting function to keep the measured pressure constant. Then, the differential pressure ΔP rapidly decreases at a certain time point, and, thereafter, the differential pressure ΔP becomes an almost constant value ΔPi. The ΔPi is larger than the ΔPn. As a cause of this state, it is thought that the filter 26 has been clogged.

Further, when the film resistance of the filter 26 has decreased, as shown in a curved line Ld, the differential pressure ΔP increases from the time point of activation of the pump 25. However, this differential pressure ΔP has a value smaller than that of the differential pressure ΔPn in the normal state. Then, the differential pressure ΔP becomes an almost constant value ΔPd after a certain time point. The ΔPd is smaller than the ΔPn. As a cause of this state, it is thought that the filter 26 is in a break-through state or that the filter 26 has air bubbles present therein.

As described above, the differential pressure ΔP is measured during the chemical liquid supply, and thereby a change in the film resistance of the filter 26 can be detected. Further, the film resistance of the filter 26 can be changed, depending on a break-through or clogged state of the filter 6 or the presence or absence of air bubbles in the filter 26. Accordingly, by measuring the differential pressure ΔP, a state of the filter 26 can be directly determined.

The filter state determination unit 31 acquires differential pressure time information representing a change in the differential pressure with respect to time, which has been calculated from pressures measured by the primary side pressure gauge 27 and the secondary side pressure gauge 28. Then, the filter state determination unit 31 compares this information with differential pressure time information of the normal state, thereby determines a state of the filter 26, and then outputs this result. Specifically, as a result of comparison, if the differential pressure in the generated differential pressure time information is larger than the differential pressure in the differential pressure time information of the normal state, the filter state determination unit 31 determines that a clogged state has occurred in the filter 26. On the other hand, as a result of comparison, if the differential pressure in the generated differential pressure time information is smaller than the differential pressure in the differential pressure time information of the normal state, the filter state determination unit 31 determines that a break-through state has occurred in the filter 26 or that air bubbles are present in the filter 26. Further, as a result of comparison, if the differential pressure in the generated differential pressure time information is the same as the differential pressure in the differential pressure time information of the normal state, the filter state determination unit 31 determines that the filter 26 is in the normal state. Here, a differential pressure value at each time point in the differential pressure time information of the normal state may be set have a range in which the filter 26 is deemed to be in the normal state.

As shown in FIGS. 2 and 3, when the film resistance of the filter 26 has increased, the differential pressure takes a value larger than that of the differential pressure of the normal state. On the other hand, when the film resistance of the filter 26 has decreased, the differential pressure takes a value smaller than that of the differential pressure of the normal state. Accordingly, if a range is defined for the differential pressure time information of the normal state of the filter 26, an increase or decrease in the film resistance of the filter 26 can be determined. Thus, the differential pressure time information to be acquired can be set by use of a period from the time point of activation of the pump 25 to an arbitrary time point.

Here, as a filter state determination method performed by the filter state determination unit 31, there is a method of comparing a waveform representing an acquired state of the differential pressure with respect to time, i.e., the differential pressure time information, with a waveform representing a reference state of the differential pressure with respect to time. Other than this, there may be used a method of comparing a differential pressure value in the differential pressure time information, at a time point of a lapse of a predetermined time since the time point of activation of the pump 25, with the corresponding differential pressure value of the normal state. In this case, as shown in FIGS. 2 and 3, when a certain time has elapsed since the time point of activation of the pump 25, the differential pressure has an almost constant value with respect to time, not only in the normal state but also in an abnormalities state. Accordingly, the predetermined time is preferably set to a value at which the differential pressure has an almost constant value.

Further, when the secondary side pressure gauge 28 does not have a pressure control function, as shown in FIG. 2, when a certain time has elapsed since the time point of activation of the pump 25, the differential pressure has an almost constant value with respect to time. Thus, in this case, a state of the filter 26 may be determined by comparing a differential pressure value, which is obtained after the inclination of the differential pressure with respect to time has changed, with the corresponding differential pressure value of the normal state.

The filter state determination unit 31 may output information indicating an abnormal state to an alarm device equipped in the chemical liquid supply system, or may cause a display part included in the monitoring apparatus 30 to display information indicating an abnormal state.

Further, the filter state determination unit 31 also determines a state of the filter 26 as to whether the filter 26 has completed its set-up, after the filter 26 is mounted or after the filter 26 is replaced. Also in this case, after the pump 25 is activated to fill the filter 26 with the chemical liquid, the differential pressure between the primary side pressure gauge 27 and the secondary side pressure gauge 28 is measured. If the differential pressure falls within a set-up completion range, the filter state determination unit 31 judges that the filter 26 is in a sufficiently wetted state without air bubbles present therein and thus the filter 26 has come into a usable set-up state.

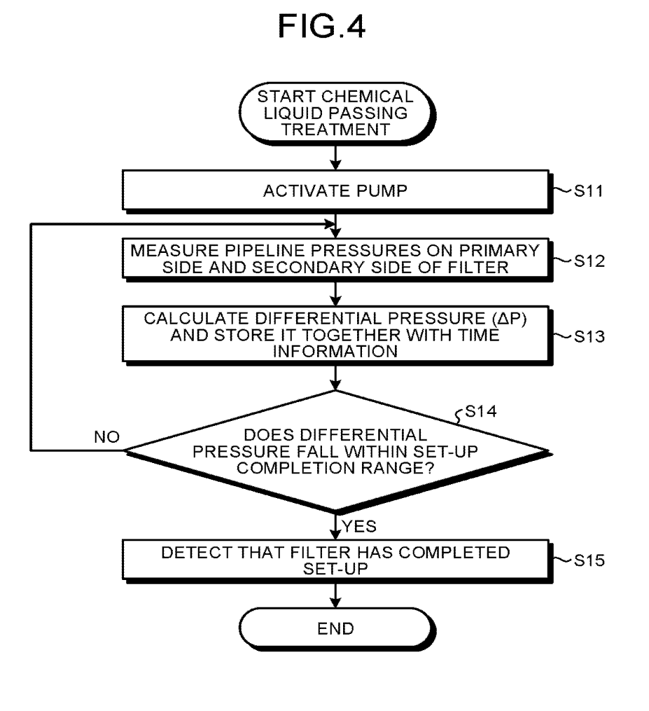

Here, a process of determining a state of the filter 26 will be described. At first, an explanation will be given of a chemical liquid passing treatment performed when the filter 26 is attached. This is a process performed after the filter 26 is replaced and before the filter 26 is used, and a state of the filter is determined also at this time. FIG. 4 is a flow chart showing an example of a procedure of a chemical liquid passing treatment performed when the filter is attached. When the pressurized gas is supplied into the chemical liquid supply part 21, the chemical liquid is supplied from inside the chemical liquid supply part 21 to the chemical liquid buffer 22. Consequently, the chemical liquid buffer 22 comes into a state holding therein a predetermined amount of chemical liquid. Then, the pump 25 is activated (step 211), and thereby the chemical liquid inside the chemical liquid buffer 22 is supplied through the filter 26 and is delivered from the nozzle 24.

Before and after the chemical liquid passes through the filter 26, pipeline pressures on the primary side and secondary side of the filter 26 are measured respectively by the primary side pressure gauge 27 and the secondary side pressure gauge 28 (step 222). The measurement values are sent to the monitoring apparatus The filter state determination unit 31 of the monitoring apparatus 30 calculates a difference (differential pressure) ΔP between the primary side pressure and the secondary side pressure, and stores it together with time information (step S13). Then, the filter state determination unit 31 determines whether the differential pressure falls within a set-up completion range (step S14). The set-up completion range corresponds to differential pressure values, with which the chemical liquid is delivered in a sufficiently wetted state without containing air bubbles, if the chemical liquid delivered from the nozzle 24 onto a processing object is observed after a start of the chemical liquid passing through the filter 26.

When the differential pressure does not fall within the set-up completion range (NO in the step S14), this means that the chemical liquid passing treatment is insufficient and the filter 26 has air bubbles remaining therein, and so the processing returns back to the step S12.

On the other hand, when the differential pressure falls within the set-up completion range (YES in the step 314), this means that the filter 26 is in a sufficiently wetted state without air bubbles present therein, so the filter state determination unit 31 detects that the filter 26 has completed its set-up (step S15). As a result, the processing ends. Thereafter, a processing object is placed below the nozzle 24, and then a chemical liquid supply process is performed by use of the chemical liquid supply system.

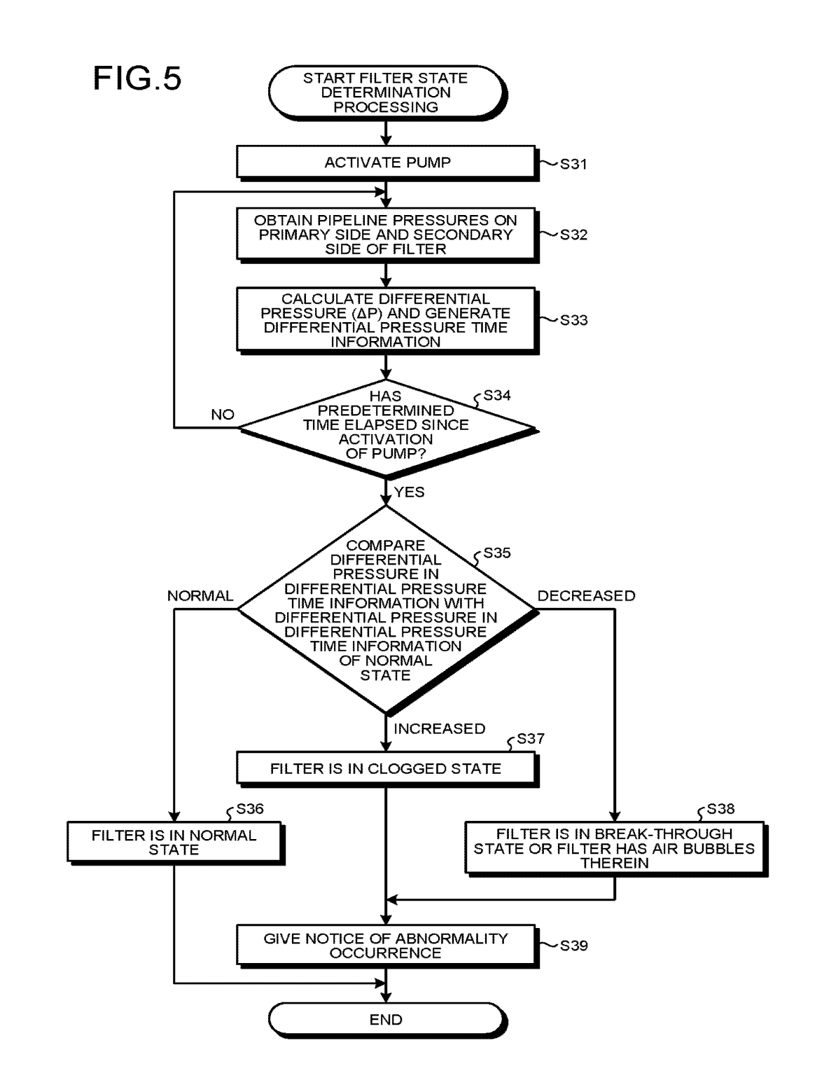

Next, an explanation will be given of a filter state determination method performed in the chemical liquid supply system. FIG. 5 is a flow chart showing an example of the process procedure of a filter state determination method according to the first embodiment. At first, a wafer treated as a processing object is placed in the chemical liquid process apparatus, and then the pump 25 is activated (step S31).

Thereafter, the filter state determination unit 31 of the monitoring apparatus 30 obtains a primary side pipeline pressure measured by the primary side pressure gauge 27 and a secondary side pipeline pressure measured by the secondary side pressure gauge 28 (step 332), and then calculates their differential pressure ΔP and thereby generates the differential pressure time information (step 333). Then, the filter state determination unit 31 determines whether a predetermined time has elapsed since the time point of activation of the pump 25 (step S34). If the predetermined time has not yet elapsed (NO in the step S34), the processing returns back to the step S32.

On the other hand, when the predetermined time has elapsed (YES in the step 334), the filter state determination unit 31 compares the differential pressure in the generated differential pressure time information with the differential pressure in the differential pressure time information of the normal state of the filter 26 (step When the differential pressure in the generated differential pressure time information shows values equal to those of the differential pressure in the differential pressure time information of the normal state (NORMAL in the step 335), i.e., when the differential pressure in the generated differential pressure time information falls within the differential pressure range indicated by the differential pressure time information of the normal state, the filter state determination unit 31 determines that the filter is in the normal state (step S36), and the processing ends. Thereafter, the chemical liquid is delivered onto the processing object.

However, when the differential pressure in the generated differential pressure time information has increased as compared with the differential pressure in the differential pressure time information of the normal state (INCREASED in the step S35), the filter state determination unit 31 determines that the film resistance of the filter 26 has increased and thus the filter 26 is in an abnormal state. Specifically, the filter state determination unit 31 determines that the filter 26 is in a clogged state (step S37).

Further, when the differential pressure in the generated differential pressure time information has decreased as compared with the differential pressure in the differential pressure time information of the normal state (DECREASED in the step S35), the filter state determination unit 31 determines that the film resistance of the filter 26 has decreased and thus the filter 26 is in an abnormal state. Specifically, the filter state determination unit 31 determines that the filter 26 is in a break-through state or that the filter 26 has air bubbles present therein (step S38).

After the step S37 or S38, the filter state determination unit 31 gives notice of abnormality occurrence (step S39), and then the processing ends. For example, the abnormality occurrence notification may be performed by giving notice of an abnormality of the filter 26 together with a state of the filter 26 to a display part (not shown), or may be performed by giving notice of an abnormality of the filter 26 by use of an indicator (not shown) for indicating it.

In the first embodiment, the primary side pressure gauge 27 and the secondary side pressure gauge 22 are disposed on the fore and back sides of the filter 26, and the differential pressure time information is generated such that it represents the differential pressure between pressure values measured by the primary side pressure gauge 27 and the secondary side pressure gauge 28 in a period until a predetermined time point since the activation of the pump 25. Then, the differential pressure in the generated differential pressure time information is compared with the differential pressure in the differential pressure time information of the normal state of the filter 26. Consequently, it is possible to determine, based on the differential pressure, a state of the filter 26 including a break-through or clogged state of the filter or the presence or absence of air bubbles in the filter 26. As a result, it is possible to address an abnormal state before delivering the chemical liquid onto the processing object, without making determination by observing a state of the chemical liquid actually delivered from the nozzle 24 onto the processing object.

Further, after the filter 26 is replaced, the differential pressure between the fore and back sides of the filter 26 is continuously measured from a start of the chemical liquid supply. Consequently, if the differential pressure falls within the set-up completion range, the set-up of the filter 26 can be detected as being completed. As a result, it is possible to confirm that the filter 26 is in a sufficiently wetted state without air bubbles remaining therein, without delivering the chemical liquid onto the processing object.

In the explanation described above, the pump 25 is used to pneumatically feed the chemical liquid through the chemical liquid supply pipeline 23b to the nozzle 24, but this is not limiting. For example, a gas, such as N₂ gas, may be used to pneumatically feed the chemical liquid through the chemical liquid supply pipeline 23b to the nozzle 24, without disposing the pump 25.

### Second Embodiment

In the first embodiment, the differential pressure of the chemical liquid passing through the filter is compared with the differential pressure of the normal state, and thereby a state of the filter is determined. In the second embodiment, an explanation will be given of a case where a state of a chemical liquid delivered from the chemical liquid supply system is correlated with the differential pressure, and thereby a state of the filter is determined.

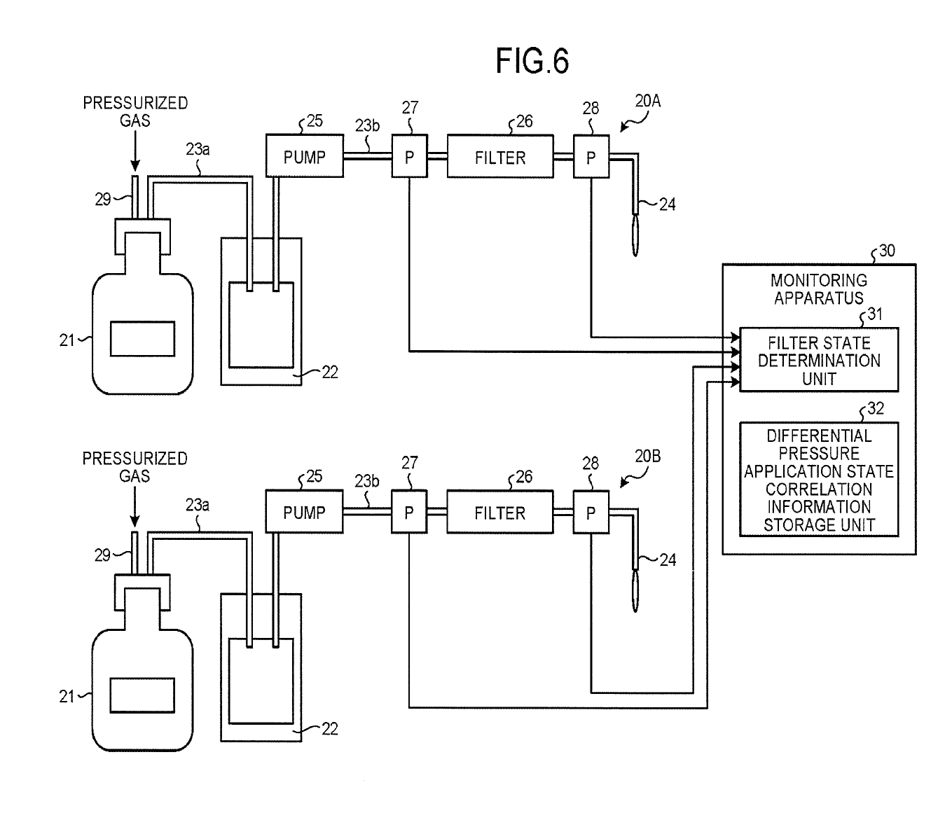

FIG. 6 is a view showing a schematic configuration example of a chemical liquid supply system according to the second embodiment. The chemical liquid supply system according to the second embodiment has a configuration in which a plurality of chemical liquid supply apparatuses 20A, 20B, . . . are connected to the monitoring apparatus 30. Each of the chemical liquid supply apparatuses 20A, 20B, . . . is the same as the chemical liquid supply apparatus 20 described in the first embodiment. Here, the plurality of chemical liquid supply apparatuses 20A, 20B, . . . connected to the monitoring apparatus 30 are supposed to have the same configuration as each other. The same configuration means a state where each of the components has the same performance, for example.

The monitoring apparatus 30 includes a differential pressure application state correlation information storage unit 32 and a filter state determination unit 31. The differential pressure application state correlation information storage unit 32 stores differential pressure application state correlation information that correlates the differential pressure between the fore and back sides of the filter 26 with the application (coating) state of the chemical liquid onto the processing object. The differential pressure application state correlation information is information that defines a differential pressure range in which the application state of the chemical liquid onto the processing object becomes normal, and a differential pressure range in which the application state of the chemical liquid onto the processing object becomes abnormal. For example, this is obtained by an experimental or actual process performed in one of the chemical liquid supply apparatuses 20 connected to the monitoring apparatus 30.

The filter state determination unit 31 determines whether the differential pressure between the primary side pipeline pressure and the secondary side pipeline pressure falls within the differential pressure range in which the application state of the chemical liquid becomes normal with reference to the differential pressure application state correlation information. When the differential pressure falls within the differential pressure range in which the application state of the chemical liquid becomes normal, the filter state determination unit 31 determines that the filter 26 is in the normal state, and continues the process accordingly. On the other hand, when the differential pressure falls within the differential pressure range in which the application state of the chemical liquid becomes abnormal, the filter state determination unit 31 determines that the filter 26 is in an abnormal state, and outputs information suggesting replacement of the filter 26. For example, the filter state determination unit 31 may output information indicating an abnormality to an alarm device, or may cause a display part included in the monitoring apparatus 30 to display information indicating an abnormal state or information suggesting replacement of the filter 26. Here, the constituent elements corresponding to those of the first embodiment are denoted by the same reference symbols, and their description will be omitted.

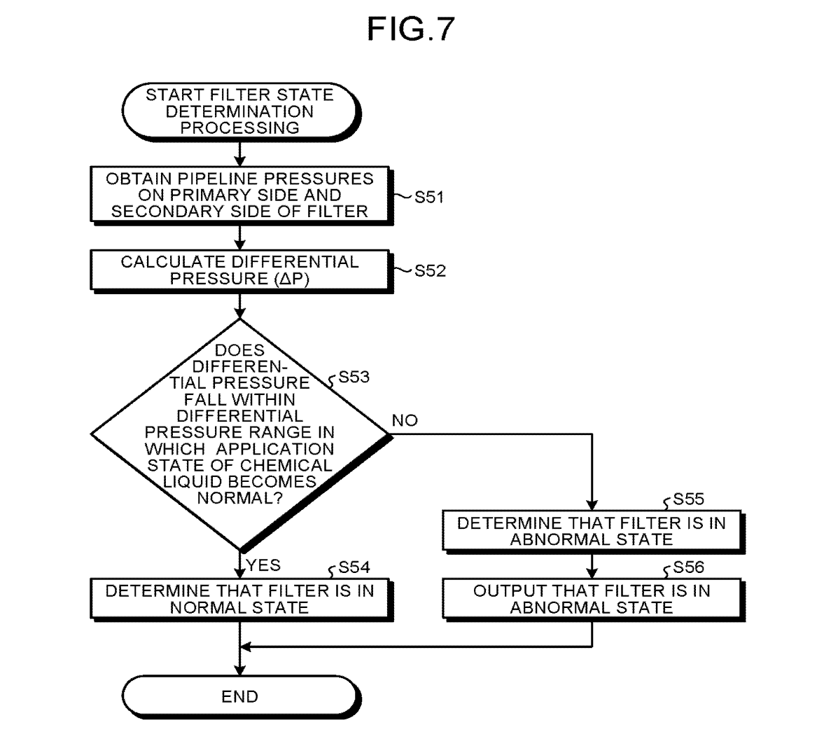

FIG. 7 is a flow chart showing an example of the process procedure of a filter state determination method according to the second embodiment. In the example shown in FIG. 7, the differential pressure application state correlation information is acquired by use of the first chemical liquid supply apparatus 20A, and is then utilized for determining whether the chemical liquid can be normally supplied when the chemical liquid is supplied onto a processing object by use of the second chemical liquid supply apparatus 20B having the same configuration as the first chemical liquid supply apparatus 20A.

At first, the filter state determination unit 31 of the monitoring apparatus 30 obtains a primary side pipeline pressure measured by the primary side pressure gauge 27 and a secondary side pipeline pressure measured by the secondary side pressure gauge 28 in second chemical liquid supply apparatus 20B (step S51). Then, the filter state determination unit 31 calculates a differential pressure ΔP (step S52).

Thereafter, the filter state determination unit 31 determines whether the calculated differential pressure falls within the differential pressure range in which the application state of the chemical liquid becomes normal with reference to the differential pressure application state correlation information (step S53). When the calculated differential pressure falls within the differential pressure range in which the application state of the chemical liquid becomes normal (YES in the step S53) the filter state determination unit 31 determines that the filter is in the normal state (step S54), and the processing ends.

On the other hand, when the calculated differential pressure does not fall within the differential pressure range in which the application state of the chemical liquid becomes normal (NO in the step S53), the monitoring apparatus 30 determines that the filter is in an abnormal state (step S55). Then, the monitoring apparatus 30 outputs that the filter is in an abnormal state (step S56), and the processing ends.

In the explanation described above, the differential pressure application state correlation information is exemplified by information that defines a differential pressure range in which the application state of the chemical liquid onto the processing object becomes normal, and a differential pressure range in which the application state of the chemical liquid onto the processing object becomes abnormal. However, the correlation information may define only one of the differential pressure range in which the application state of the chemical liquid onto the processing object becomes normal, and the differential pressure range in which the application state of the chemical liquid onto the processing object becomes abnormal.

In the chemical liquid supply system according to the second embodiment, a plurality of chemical liquid supply apparatuses 20A, 20B, . . . having the same configuration are provided, and are set to share in common the differential pressure application state correlation information for confirming whether the application state of the chemical liquid is abnormal. Consequently, it is possible to determine, based on a differential pressure calculated from the primary side pipeline pressure and the secondary side pipeline pressure of the filter 26, measured in one of the chemical liquid supply apparatuses 20, whether the chemical liquid can be normally applied onto the processing object in another one of the chemical liquid supply apparatuses 20 having a similar configuration.

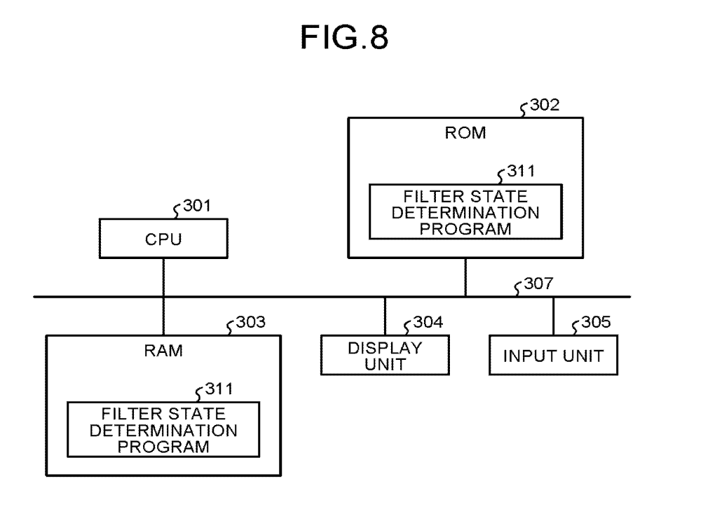

Next, an explanation will be given of the hardware configuration of the monitoring apparatus 30. FIG. 8 is a view showing the hardware configuration of the monitoring apparatus. The monitoring apparatus 30 includes a CPU (Central Processing Unit) 301, a ROM (Read Only Memory) 302, a RAM (Random Access Memory) 303, a display unit 304, and an input unit 305. In the monitoring apparatus 30, the CPU 301, the ROM 302, the RAM 303, the display unit 304, and the input unit 305 are connected to each other via a bus line 307.

The CPU 301 uses a filter state determination program 311, which is a computer program, to determine a state of the filter used in the chemical liquid supply apparatus 20. The filter state determination program 311 is formed of a computer program product executable by a computer and including a recording medium prepared to be readable by a computer and to be non-transitory (non-transitory computer-readable recording medium), which contains a plurality of commands for determining a state of the filter by the monitoring apparatus 30. According to the filter state determination program 311, the plurality of commands cause the computer to determine a state of the filter by the monitoring apparatus 30.

The display unit 304 is formed of a display device, such as a liquid crystal monitor, and is configured to display filter state determination results and so forth, based on instructions from the CPU 301. The input unit 305 is formed of a mouse and/or a keyboard, and is used for inputting instruction information, such as commands, externally input by a user. The instruction information input into the input unit 305 is sent to the CPU 301.

The filter state determination program 311 is stored in the ROM 302, and can be loaded into the RAM 303 via the bus line 307. FIG. 9 shows a state where the filter state determination program 311 has been loaded into the RAM 303.

The CPU 301 is configured to execute the filter state determination program 311 loaded in the RAM 303. More specifically, according to the monitoring apparatus 30, in response to an instruction input from the input unit 305 by the user, the CPU 301 reads the filter state determination program 311 out of the ROM 302, and loads it into a program storage region formed inside the RAM 303, to perform various processes. The CPU 301 temporarily stores various data, generated by these various processes, into a data storage region formed inside the RAM 303.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the, inventions. The accompanying claims and their equivalents are intended to cover such forms or modifications as would fall within the scope and spirit of the inventions.

What is claimed is:

1. A chemical liquid supply system comprising: a chemical liquid supply apparatus configured to supply a chemical liquid onto a processing object; and a monitoring apparatus, wherein
the chemical liquid supply apparatus includes
a nozzle configured to supply the chemical liquid, through a pipeline, onto the processing object,
a filter disposed on the pipeline,
a first pressure gauge disposed on the pipeline, at a chemical liquid supply-source side of the filter, and
a second pressure gauge disposed on the pipeline, at a chemical liquid delivery side of the filter, and
the monitoring apparatus is configured to determine a state of the filter based on first differential pressure time information, the first differential pressure time information being information in which a differential pressure is acquired in a period until a time point of a lapse of a predetermined time since a start of pneumatic feeding of the chemical liquid to the nozzle, the differential pressure being a difference between a first pressure value measured by the first pressure gauge and a second pressure value measured by the second pressure gauge.

2. The chemical liquid supply system according to claim 1, wherein, when the differential pressure in the first differential pressure time information is same as the differential pressure in second differential pressure time information of a normal state, the monitoring apparatus determines that the filter is in a normal state.

3. The chemical liquid supply system according to claim wherein, when the differential pressure in the first differential pressure time information is not same as the differential pressure in the second differential pressure time information, the monitoring apparatus determines that the filter is in an abnormal state.

4. The chemical liquid supply system according to claim 3, wherein the monitoring apparatus outputs information indicating the abnormal state.

5. The chemical liquid supply system according to claim 3, wherein, when the differential pressure in the first differential pressure time information is larger than a differential pressure range of the normal state, the monitoring apparatus determines that a clogged state has occurred in the filter.

6. The chemical liquid supply system according to claim 3, wherein, when the differential pressure in the first differential pressure time information is smaller than the differential pressure in the second differential pressure time information, the monitoring apparatus determines that a break-through state has occurred in the filter or that air bubbles are present on the filter.

7. The chemical liquid supply system according to claim 1, wherein, after the filter is mounted or after the filter is replaced, the monitoring apparatus detects that the filter completes set-up when the differential pressure comes to fall within a predetermined differential pressure range.

8. The chemical liquid supply system according to claim 1, wherein the monitoring apparatus determines whether the chemical liquid is to be normally applied onto the processing object based on calculated differential pressure with reference to differential pressure application state correlation information, the differential pressure application state correlation information representing relationship between the differential pressure and an application state of the chemical liquid onto the processing object.

9. The chemical liquid supply system according to claim 8, wherein
the chemical liquid supply apparatus includes a first chemical liquid supply apparatus and a second chemical liquid supply apparatus having a same configuration as the first chemical liquid supply apparatus, the first chemical liquid supply apparatus and the second chemical liquid supply apparatus being connected to the monitoring apparatus,
the differential pressure application state correlation information is generated based on a process performed in the first chemical liquid supply apparatus, and
the monitoring apparatus s whether the chemical liquid is to be normally applied onto a processing object in the second chemical liquid supply apparatus, based on difference between pressure values measured by the first pressure gauge and the second pressure gauge of the second chemical liquid supply apparatus, with reference to the differential pressure application state correlation information.

10. The chemical liquid supply system according to claim 1, wherein the chemical liquid is a resist liquid, developing solution, or cleaning liquid.

11. A chemical liquid supply method supplying a chemical liquid onto a processing object, the method comprising:
pneumatically feeding the chemical liquid into a pipeline configured to supply the chemical liquid from a supply source onto the processing object;
measuring a first pipeline pressure at a supply-source side of a filter disposed on the pipeline, and a second pipeline pressure at a processing-object side of the filter;
calculating a differential pressure between the first pipeline pressure and the second pipeline pressure;
creating first differential pressure time information that records the differential pressure together with measurement time points of the first pipeline pressure and the second pipeline pressure in a period until a time point of a lapse of a predetermined time since a start of pneumatic feeding of the chemical liquid; and
determining a state of the filter by comparing the differential pressure in the first differential pressure time information with the differential pressure in second differential pressure time information of a normal state of the filter.

12. The chemical liquid supply method according to claim 11, wherein the determining the state of the filter includes determining that the filter is in a normal state, when the differential pressure in the first differential pressure time information is same as the differential pressure in the second differential pressure time information

13. The chemical liquid supply method according to claim 12, wherein the determining the state of the filter includes determining that the filter is in an abnormal state, when the differential pressure in the first differential pressure time information is different from the differential pressure in the second differential pressure time information

14. The chemical liquid supply method according to claim 13, further comprising outputting information indicating the abnormal state of the filter.

15. The chemical liquid supply method according to claim 13, wherein the determining the state of the filter includes determining that a clogged state has occurred in the filter, when the differential pressure in the first differential pressure time information is larger than the differential pressure in the second differential pressure time information.

16. The chemical liquid supply method according to claim 13, wherein the determining the state of the filter includes determining that a break-through state has occurred in the filter or that air bubbles are present on the filter, when the differential pressure in the first differential pressure time information is smaller than the differential pressure in the second differential pressure time information.

17. The chemical liquid supply method according to claim 11, wherein the determining the state of the filter includes detecting that the filter completes set-up when the differential pressure in the first differential pressure time information comes to fall within a predetermined differential pressure range, after the filter is mounted or after the filter is replaced.

18. The chemical liquid supply method according to claim 11, wherein the determining the state of the filter includes determining whether the chemical liquid is to be normally applied onto the processing object, based on calculated differential pressure with reference to differential pressure application state correlation information, the differential pressure application state correlation information representing relationship between the differential pressure and an application state of the chemical liquid onto the processing object.

19. The chemical liquid supply method according to claim 18, further comprising calculating the differential pressure application state correlation information by use of a first chemical liquid supply apparatus including a first supply source, a first pipeline, and a first filter,
wherein the determining the state of the filter includes determining whether the chemical liquid is to be normally applied onto a processing object in a second chemical liquid supply apparatus based on the calculated differential pressure with reference to the differential pressure application state correlation information, the second chemical liquid supply apparatus including a second supply source, a second pipeline, and a second filter and having a same configuration as the first chemical liquid supply apparatus.

20. The chemical liquid supply method according to claim 11, wherein the chemical liquid is a resist liquid, developing solution, or cleaning liquid.
